(19) United States
(12) Patent Application Publication
(10) Pub. No.: US 2024/0425986 A1
(43) Pub. Date: Dec. 26, 2024

(54) GAS INJECTION SYSTEM FOR USE IN A PROCESSING CHAMBER

(71) Applicant: ASM IP Holding B.V., Almere (NL)

(72) Inventors: Junwei Su, Chandler, AZ (US); Jiwen Xiang, Gilbert, AZ (US); Zhizhong Chen, Tempe, AZ (US); Yang Wang, Chandler, AZ (US); Xing Lin, Chandler, AZ (US)

(21) Appl. No.: 18/746,189

(22) Filed: Jun. 18, 2024

Related U.S. Application Data
(60) Provisional application No. 63/522,864, filed on Jun. 23, 2023.

(51) Int. Cl. C23C 16/455; C23C 16/52

(52) U.S. Cl. CPC C23C 16/45561; C23C 16/52

(57) ABSTRACT

Methods and apparatuses for decoupling the tuning of cross-substrate thickness variation and cross-substrate resistance variation in a gas injection system are described. A controller in a gas injection system may deposit, via control of the plurality of first mass flow controllers (MFCs) and the plurality of second MFCs, a material layer deposited on a substrate. The controller may adjust, via control of the plurality of first MFCs, a cross-substrate thickness variation of the material layer. The controller may adjust, via control of the plurality of second MFCs and independent of the cross-substrate thickness variation, cross-substrate resistivity variation of the material layer.

### CROSS-REFERENCE TO RELATED APPLICATION(S)

This application claims the benefit of U.S. Provisional Application 63/522,864 filed on Jun. 23, 2023, the entire contents of which are incorporated herein by reference.

### TECHNICAL FIELD

The present disclosure generally relates to gas injection systems. More particularly, the disclosure relates to an apparatus and a method for decoupling the tuning of cross-substrate thickness variation and cross-substrate resistivity variation.

### BACKGROUND

Semiconductor devices are manufactured in process chambers. One or more precursor sources, dopant sources and carrier sources may be injected into the process chamber to deposit precursor reactants onto a substrate, such as a silicon wafer. A gas injection system may include a main header (e.g., a main manifold) and an auxiliary header (e.g., an auxiliary manifold). Conventional systems may attempt to tune the thickness of the material layer deposited onto the substrate by adjusting injector settings on the main header, and subsequently tune the sheet resistivity of the material layer deposited onto the substrate by adjusting injector settings on the auxiliary header. However, tuning the sheet resistivity may negatively impact the thickness profile of the material layer deposited onto the substrate and cause interference. As a result, a conventional system may lack a mechanism to decouple the tuning of the cross-substrate thickness variation and cross-substrate resistivity variation, and thereby limit its ability to control material layer variations and provide optimal performance, throughput and efficiency in the semiconductor manufacturing process.

### SUMMARY

The following presents a simplified summary of various aspects described herein. This summary is not an extensive overview, and is not intended to identify key or critical elements or to delineate the scope of the claims. The following summary merely presents some concepts in a simplified form as an introductory prelude to the more detailed description provided below.

One or more aspects are described for tuning of the cross-substrate thickness variation and cross-substrate resistance variation independently. In one aspect, a gas injection system may include one or more of the following: a main header comprising a plurality of first mass flow controllers (MFCs) having a first mass flow rate range and an auxiliary header comprising a plurality of second MFCs having a second mass flow rate range, where the second mass flow rate range may be different from the first mass flow rate range. The main header may be coupled to a precursor source, a dopant source and a carrier source. The auxiliary header may be coupled to the dopant source and the carrier source. The system may further include a controller comprising one or more processors and memory storing computer-readable instructions that when executed by the one or more processors, cause the controller to deposit, via control of the plurality of first MFCs and the plurality of second MFCs, a material layer on a substrate. The instructions may cause the controller to adjust, via control of the plurality of first MFCs, a cross-substrate thickness variation of the material layer. The instructions may further adjust, via control of the plurality of second MFCs and independent of the cross-substrate thickness variation, cross-substrate resistivity variation of the material layer.

In some examples, a value in the second mass flow rate range may be between about 1% and about 10% of a value in the first mass flow rate range. Using MFCs with a relatively lower mass flow rate range on the auxiliary header may decouple adjustments made to flow distribution among the second MFCs on the auxiliary header from flow distribution among the first MFCs on the main header. This application may allow for tuning cross-substrate resistance (i.e., resistance uniformity) with no or minimal alterations on average substrate resistance uniformity, which is a function of total dopant flow through. The first mass flow rate range may not overlap with the second mass flow rate range. For example, the first mass flow rate range may be about 30 to about 110 standard liter per minute (SLM) and the second mass flow rate range may be about 1 to about 7 SLM. The first MFCs and the second MFCs may have different flow-rate limiting structures. For example, each of the first MFCs and each of the second MFCs may comprise an inlet port, a control valve, and an outlet port. The control valve in a first position may fluidly couple the inlet port to the outlet port. The control valve in a second position may fluidly decouple the inlet port from the outlet port. The control valve may include a valve seat and solenoid-actuated movable diaphragm. In the first position the diaphragm is apart from the valve seat such that a flow of gas from the inlet port through the valve seat to the outlet port is enabled. In the second position, the diaphragm abuts the valve seat such that the flow of gas from the inlet port through the valve seat to the outlet port is inhibited. The inlet port may comprise an orifice having an effective flow area that limits a mass flow rate of the gas from the inlet port through the control valve to the outlet port when the control valve is in the first position. The effective flow area of the orifice in each of the first MFCs may be greater than the effective flow area of the orifice in each of the second MFCs. The effective flow area in each of the first MFCs may limit the mass flow rate to within the first mass flow rate range, and the effective flow area in each of the second MFCs may limit the mass flow rate to within the second mass flow rate range. In some examples, the inlet port, the control valve, and the outlet port in each of the first MFCs may form a first mass flow-rate limiting structure that limits a mass flow rate of the gas to within the first mass flow rate range. Likewise, the inlet port, the control valve, and the outlet port in each of the second MFCs may form a second mass flow-rate limiting structure that limits the mass flow rate of the gas to within the second mass flow rate range. In some examples, the first and the second mass flow-rate limiting structures may comprise different inlet port cross sections, different outlet port cross sections, different inlet port diameters, different diaphragm-to-valve seat spacing, different outlet port diameters, or orifice plates with different effective flow areas. Each of first MFCs may be coupled with a first sensor configured to measure a first flow rate of gasses over the first mass flow rate range, and each of the second MFCs may be coupled with a second sensor configured to measure a second flow rate of gasses over the second mass flow rate range. The second sensor may have a higher sensitivity than the first sensor. The plurality of first MFCs may comprise seven MFCs, and the plurality of second MFCs may comprise three MFCs.

In another aspect, the gas injection system may include an injection flange comprising a plurality of main injection ports corresponding one-to-one with the plurality of first MFCs and a plurality of auxiliary injection ports corresponding one-to-one with the plurality of second MFCs. The plurality of first MFCs may be configured to control a flow of a precursor, a dopant and a carrier through the plurality of main injection ports to a deposition chamber. The plurality of second MFCs may be configured to control a flow of the dopant and the carrier through the plurality of auxiliary injection ports to the deposition chamber. The controller may adjust, via the plurality of second MFCs, a distribution of a flow of the carrier through the plurality of auxiliary injection ports to the deposition chamber to tune the cross-substrate resistivity variation of the material layer. The controller may adjust, via the plurality of second MFCs, a distribution of the dopant between the plurality of main injection ports on the main header and the plurality of auxiliary injection ports on the auxiliary header to tune the cross-substrate resistivity variation of the material layer. For example, a ratio of the dopant carried by the auxiliary header and the main header may be 1 to 4. The controller may adjust, via the plurality of second MFCs, a cross-substrate dopant concentration variation to tune the cross-substrate resistivity variation of the material layer.

In another aspect, the carrier source may include one or more tanks containing a carrier selected from the group consisting of nitrogen, hydrogen (H₂), and helium. The precursor source may include one or more tanks containing a precursor selected from the group consisting of trichlorosilane, dichlorosilane, silane, disilane, trisilane, and silicon tetrachloride. The dopant source may include one or more tanks containing a dopant selected from the group consisting of germane, diborane, phosphine, arsine, and phosphorus trichloride.

In a further aspect, a gas flow control method may comprise depositing, via control of a plurality of first MFCs and a plurality of second MFCs in a gas injection system, a material layer on a substrate. The plurality of first MFCs may have a first mass flow rate range, and the plurality of second MFCs may have a second mass flow rate range, where the first mass flow rate range may be different from the second mass flow rate range. The plurality of first MFCs may be connected by a main header to a precursor source, a dopant source and a carrier source. The plurality of second MFCs may be connected by an auxiliary header to the dopant source and the carrier source. The method may comprise adjusting, via control of the plurality of first MFCs, a cross-substrate thickness variation of the material layer. The method may further comprise adjusting, via control of the plurality of second MFCs and independent of the cross-substrate thickness variation, cross-substrate resistivity variation of the material layer.

Additional aspects, configurations, embodiments, and examples are described in more detail below.

### BRIEF DESCRIPTION OF DRAWINGS

The patent or application file contains at least one drawing executed in color. Copies of this patent or patent application publication with color drawing(s) will be provided by the Office upon request and payment of the necessary fee.

Some features are shown by way of example, and not by limitation, in the accompanying drawings. In the drawings, like numerals reference similar elements.

FIG. 1 illustrates an example of a reactor system in accordance with one or more illustrative aspects discussed herein;

FIG. 2 shows a schematic view of an example of a gas injection system according to one or more aspects of the disclosure;

FIG. 3 shows a block diagram of a main header and an auxiliary header for decoupling the tuning of the cross-substrate thickness variation and cross-substrate resistivity variation, according to one or more aspects of the disclosure;

FIG. 4A shows an example graph illustrating the tuning of the thickness profile and resistivity profile according to one or more aspects of the disclosure;

FIG. 4B shows another example graph illustrating the tuning of the thickness profile and resistivity profile according to one or more aspects of the disclosure;

FIG. 4C shows still another example graph illustrating the tuning of the thickness profile and resistivity profile according to one or more aspects of the disclosure;

FIG. 5 shows an example flowchart describing a process for decoupling the tuning of thickness and resistivity according to one or more aspects of the disclosure;

FIG. 6 depicts an example of a computing device that may be used in implementing one or more aspects of the disclosure; and

FIG. 7A illustrates an example mass flow metering valve of a mass flow controller (MFC), according to one or more aspects of the disclosure;

FIGS. 7B and 7C illustrate a top and side views of an example diaphragm seat of the MFC, including example effective flow areas of a main MFC and an auxiliary MFC, according to one or more aspects of the disclosure.

It will be recognized by the skilled person in the art, given the benefit of this disclosure, that the exact arrangement, sizes and positioning of the components in the figures is not necessarily to scale or required.

### DETAILED DESCRIPTION

One or more aspects of the disclosure relate to tuning of the cross-substrate thickness variation and cross-substrate resistivity variation. The present disclosure generally relates to reactor systems including a gas injection system, and to methods of using the gas injection systems to tune the thickness profile and the resistivity profile independently. The gas injection system may be used to process substrates, such as semiconductor wafers. By way of examples, the systems described herein can be used to form or grow epitaxial layers (e.g., two component and/or doped semiconductor layers) on a surface of a substrate. The gas injection system may be further used to provide etch chemistry to a substrate surface. For example, exemplary systems may provide a mixture of two or more gases (e.g., a precursor, a dopant source and a carrier source) during a deposition (e.g., growth) process and/or during an etch process. Both the deposition and etch gases can be used to grow an epitaxial material layer on a substrate.

As used herein, the term substrate may refer to any underlying material or materials upon which a layer may be deposited. A substrate may include a bulk material, such as silicon (e.g., single-crystal silicon) or other semiconductor material, and may include one or more layers, such as native oxides or other layers, overlying or underlying the bulk material. The substrate may include various topologies, such as recesses, lines, and the like formed within or on at least a portion of a layer and/or bulk material of the substrate. A substrate may comprise one or more materials including, for example, silicon (Si), germanium (Ge), germanium tin (GeSn), silicon germanium (SiGe), silicon germanium tin (SiGeSn), silicon carbide (SiC), or a group III-V semiconductor material, such as, for example, gallium arsenide (GaAs), gallium phosphide (GaP), or gallium nitride (GaN). In some examples, the substrate may comprise one or more dielectric materials including, such as, oxides, nitrides, or oxynitrides. The substrate may comprise a silicon oxide (e.g., SiO₂), a metal oxide (e.g., Al₂O₃), a silicon nitride (e.g., Si₃N₄), or a silicon oxynitride. The substrate may also comprise an engineered substrate where a surface semiconductor layer may be disposed over a bulk support with an intervening buried oxide (BOX) disposed therebetween. The substrate may contain one or more monocrystalline surfaces and/or one or more other surfaces that may comprise a non-monocrystalline surface, such as a polycrystalline surface and/or an amorphous surface. The substrate may include a layer comprising a metal, such as copper, cobalt, and the like.

The terms precursor and/or precursor gasses may refer to a gas or combination of gasses that participate in a chemical reaction that produces another compound. For example, precursor gasses may be used to grow an epitaxial layer comprising silicon carbide. Precursor gasses may include a deposition gas, a dopant gas, a carrier gas, or a combination of a deposition gas, a dopant gas or a carrier gas.

As set forth in more detail below, use of example gas injection systems as described herein may decouple the tuning of the cross-substrate thickness variation and cross-substrate resistivity variation. In contrast with conventional systems, where the MCEs on the main header and the auxiliary header may have similar configurations or flowing limiting structures, the gas injection systems in the present disclosure employ mismatched MCFs. These mismatched MCFs may be configured to have different mass flow rate ranges and allow for independent tuning of the thickness profile and the resistivity profile of a deposited material layer, such as an epitaxially formed layer on a substrate.

In the following description of the various embodiments, reference is made to the accompanying drawings, which form a part hereof, and in which is shown by way of illustration various embodiments in which aspects of the disclosure may be practiced. It is to be understood that other embodiments may be utilized and structural and functional modifications may be made without departing from the scope of the present disclosure. Aspects of the disclosure are capable of other embodiments and of being practiced or being carried out in various ways. Also, it is to be understood that the phraseology and terminology used herein are for the purpose of description and should not be regarded as limiting. Rather, the phrases and terms used herein are to be given their broadest interpretation and meaning. The use of “including” and “comprising” and variations thereof is meant to encompass the items listed thereafter and equivalents thereof as well as additional items and equivalents thereof. While various directional arrows are shown in the figures of this disclosure, the directional arrows are not intended to be limiting to the extent that bi-directional communications are excluded. Rather, the directional arrows are to show a general flow of steps and not the unidirectional movement of information. In the entire specification, when an element is referred to as “comprising” or “including” another element, the element should not be understood as excluding other elements so long as there is no special conflicting description, and the element may include at least one other element. Throughout the specification, expressions such as “at least one of a, b, and c” may include “a only,” “b only,” “c only,” “a and b,” “a and c,” “b and c,” and/or “all of a, b, and c.”

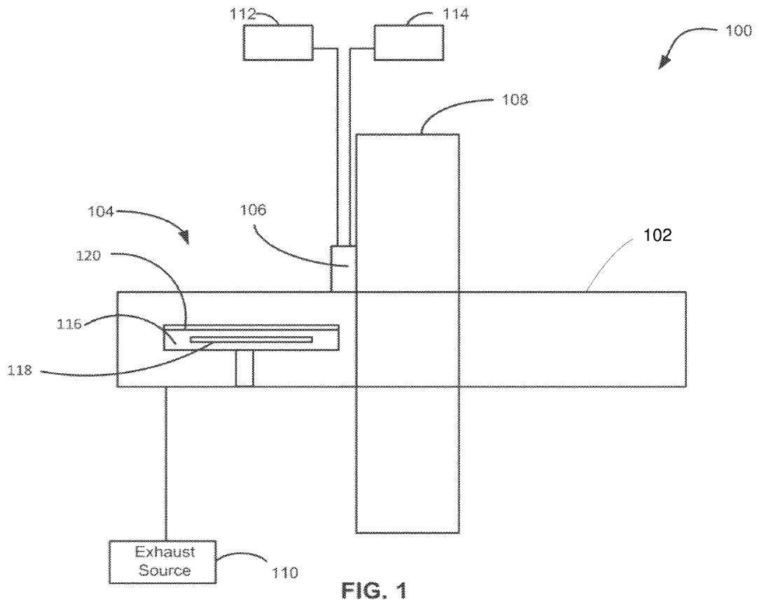

FIG. 1 illustrates an example of a reactor system. Reactor system 100 may be used for a variety of applications, such as chemical vapor deposition (CVD), plasma-enhanced CVD (PECVD), atomic layer deposition (ALD), clean processes, etch processes, and the like. Reactor system 100 may include an optional substrate handling system 102, a reaction chamber 104, a gas injection system 106, and optionally a wall 108 disposed between reaction chamber 104 and substrate handling system 102. System 100 can also include a first gas source 112, a second gas source 114, and an exhaust source 110. Although illustrated with two gas sources 112, 114, reactor system 100 can include any suitable number of gas sources. Gas sources 112, 114 can include, for example, a precursor gas, such as trichlorosilane (TCS), dichlorosilane (DCS), silane, disilane, and trisilane; a dopant source, such as a gas comprising As, P, C, Ge, and B; and a carrier gas, such as hydrogen, nitrogen, argon, helium or the like.

Reactor system 100 may include any suitable number of reaction chambers 104 and substrate handling systems 102. By way of example, reaction chamber 104 of reactor system 100 may include a cross flow, cold wall epitaxial reaction chamber, such as a system from ASM (e.g., the ASM Intrepid® reactor system).

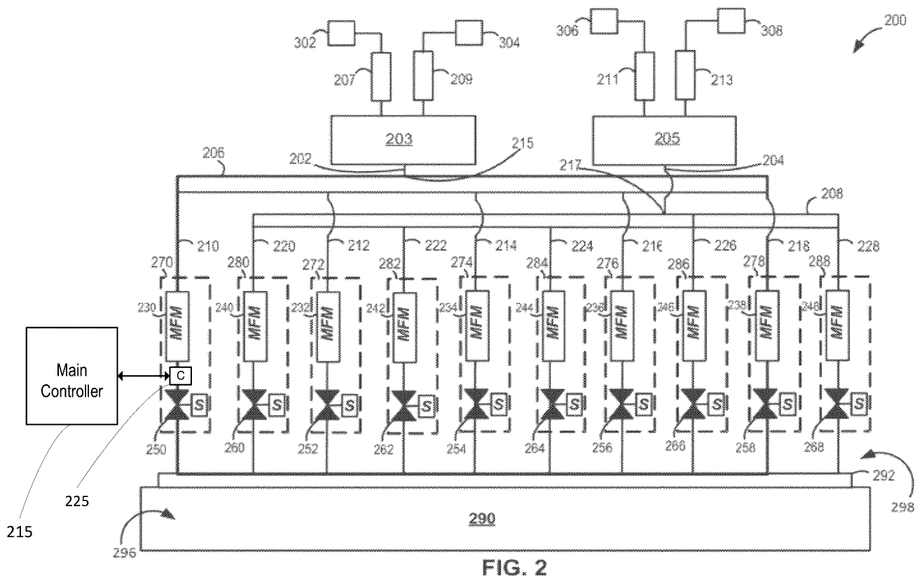

During operation of reactor system 100, substrates, such as semiconductor wafers, (not illustrated) are transferred from substrate handling system 102, to reaction chamber 104. Once substrates are transferred to reaction chamber 104, one or more gases from gas sources 112, 114, such as precursors, dopants, carrier gases, and/or purge gases may be introduced into reaction chamber 104 via gas injection system 106. As set forth in more detail below, gas injection system 106 may be used to meter and control gas flow of one or more gases from first gas source 112 and second gas source 114 during substrate processing and to provide desired flow rates of such gas(es) to reaction chamber 104. A more detailed description of the gas injection system will be provided with reference to FIG. 2.

FIG. 2 shows a schematic view of an example of a gas injection system. Gas injection system 200 may include a first gas supply line 202 coupled to a first gas source 203, which may be similar to gas source 112; and a second gas supply line 204 coupled to a second gas source 205, which may be similar to gas source 114. Gas injection system 200 may include a first gas header 206 (e.g., a main header) coupled to first gas supply line 202 and a second gas header 208 (e.g., an auxiliary header or aux header) coupled to second gas supply line 204. First gas header 206 may include a plurality of first gas outlets 210-218, and second gas header 208 may include a plurality of second gas outlets 220-228. First gas header 206 and second gas header 208 may be configured to receive gas from one or more gas lines (e.g., first and second gas lines 202, 204) and distribute the gas into one or more first channels and one or more second channels, which are respectively defined, in part, by first gas outlets 210-218 and second gas outlets 220-228.

In the example of FIG. 2, each of the first and second gas streams from first gas source 203 and second gas source 205 may be divided into five first channels and five second channels. Although first gas header 206 and second gas header 208 are illustrated to connect to five channels, it is possible for gas injection systems in accordance with this disclosure to include any suitable number of channels for the respective gases. For example, first gas header 206 may be a main gas header, which connects to seven channels, while second gas header 208 may be an auxiliary gas header, which connects to three channels.

Gas injection system 200 may include flow controllers 207-213 that control mass flow rates of first gas source 203 and/or second gas source. Gas injection system 200 may include a plurality of flow sensors 230-248 coupled to first and second gas outlets 210-228. Flow sensors 230-248 may monitor the mass flow rates of gas mixtures and to provide real-time and/or historical flow rate information to a user for each channel, which may be presented on a graphical user interface. Additionally, and/or alternatively, flow sensors 230-248 may be coupled to a main controller 215 and to gas valves 250-258 to provide controlled flow ratio of the gases through gas valves 250-268. The main controller 215 may have control of the function of gas valves 250-268. Gas valves 250-268 may include any suitable device to meter flow of a gas. Flow sensors 230-248 and gas valves 250-268 may form mass flow controllers. For example, flow meter 230 and gas valve 250 may form or be part of a mass flow controller 270. Similarly, flow sensors 232-248 and gas valves 252-258 may form or be part of mass flow controllers 272-288. The main controller 215 may control a flow through a channel of gas injection system 200 using mass flow controllers (MFCs) 270-288. Each of the MFCs 270-288 may include a controller 225 within the dashed outline of the corresponding MFCs, each of which may then be in communication with the main controller 215. Although only MFC 270 in FIG. 2 is illustrated to contain a controller 225, MFCs 270-288 may each contain a controller similarly to controller 225 and each controller within MFCs 270-288 may be in communication with the main controller 215. Operatively, the main controller 215 may provide a mass flow rate target to controller 225 in each of MFCs 270-288. In turn, each controller 225 may throttle the solenoid metering valve (e.g., solenoid metering valves 250-268), according to a comparison of the received mass flow rate target and a mass flow rate reported by the MFM (e.g., MFMs 230-246). The main controller 215 may send different mass flow rate targets to each of the main MFCs and auxiliary MFCs, thereby adjusting cross-substrate flow and cross-substrate material layer properties.

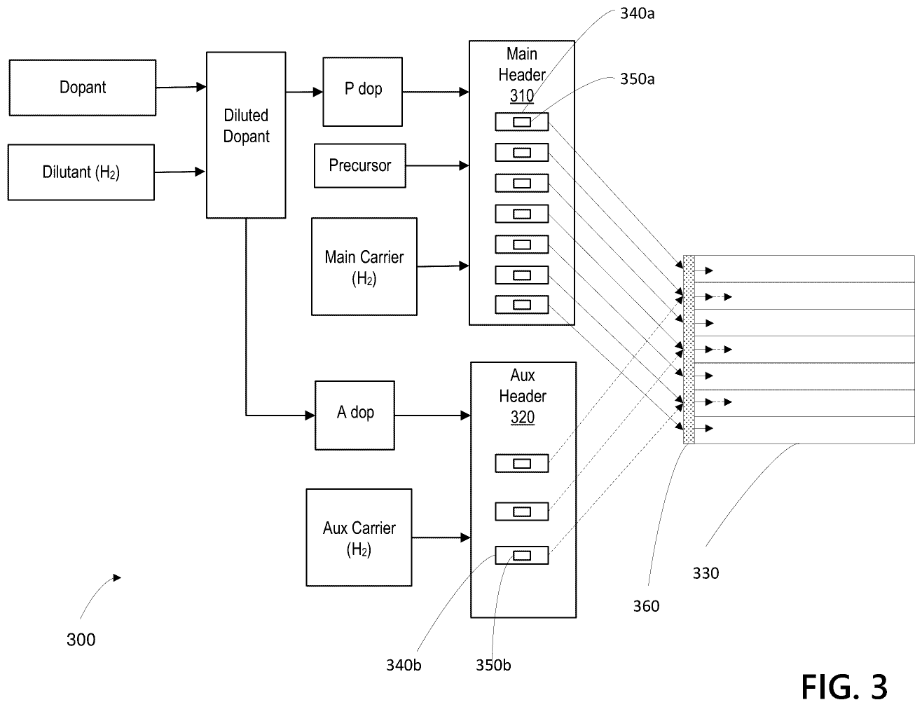

FIG. 3 shows a block diagram of a main header and an auxiliary header for decoupling the tuning of the cross-substrate thickness variation and cross-substrate resistivity variation. FIG. 3 shows a view of an example gas injection system 300. The gas injection system 300 may demonstrate the flow of various gas resources into a reaction chamber via a primary header and an auxiliary header. As illustrated in FIG. 3, gas injection system 300 may include a main header 310 (e.g., a main automatic gas injection (AGI)), and an aux header 320 (e.g., an auxiliary (aux) AGI). The main header 310 may be a main header connecting to an injection flange 360 having a first set of injection ports (e.g., the main injection ports), and the aux header 320 may be an auxiliary header connecting to the injection flange 360 having a second set of injection ports (e.g., the auxiliary injection ports). The main header may comprise a plurality of first mass flow controllers (MFCs) 340a. The aux header may comprise a plurality of second MFCs 340b. Each of the first MFCs 340a (e.g., main MFCs) may have a first flow-rate limiting structure 350a, such as a control valve (e.g., diaphragm valve) or an orifice plate. Each of the second MFCs (e.g., aux MFCs) 340b may have a second flow-rate limiting structure 350b, such as a control valve (e.g., diaphragm valve) or an orifice plate. These flow-rate limiting structures may define different effective flow areas. Due to the differences in their flow-rate limiting structures, the plurality of first MFCs may have a first mass flow rate range, and the plurality of second MFCs may have a second mass flow rate range.

In the example of FIG. 3, the main header 310 comprises seven (7) mass flow controllers (e.g., main MFCs) that are individually connected to seven main injection ports located on the injection flange 360. The aux header 320 comprises three (3) MFCs (e.g., aux MFCs) individually connected to three aux injection ports located on the injection flange 360. While seven MFCs on the main header and three MFCs on the aux header are described, main header may have any number of main MFCs and the aux header may have any number of aux MFCs. The three aux injection ports may be distributed among the seven main injection ports. The main header 310 may be coupled to a precursor source, a dopant source and a carrier source, and the aux header 320 may be coupled to the dopant source and the carrier source. For example, silicon precursor sources (e.g., TCS), dopant sources (e.g., the primary dopant (e.g., “P-dopant”)), and carrier sources (e.g., hydrogen (H₂)) may be flown to the main header 310 to provide silicon precursors and dopants to the reaction chamber through the main injection ports on the injection flange 360. The dopant source and the carrier source may be further connected to the aux header 320 to provide additional dopants (e.g., “A-dopant”) to the reaction chamber through the auxiliary injection ports on the injection flange 360. During deposition, a silicon precursor flow and a first dopant (e.g., “P-dopant”) flow may be provided through the main header 310 to the injection flange and intermixed with a second dopant (e.g., “A-dopant”) flow provided through the aux header 320.

In a conventional system, the precursors and the dopants may be injected into the reaction chamber with one set of injector settings. For example, the mass flow rate ranges as controlled by the MFCs on the main header and the auxiliary header may be the same. The system would typically tune the thickness profile first by changing the injector settings such as a mass flow rate on the main header to obtain a desired thickness profile. To tune the resistivity profile, the system may subsequently change the injector settings such as a mass flow rate on the auxiliary header, which may in turn impact the thickness profile. Similarly, if the injector settings are changed to tune the thickness, these changes may also impact the resistivity profile. In such conventional system, the main header and aux header may have the same or similar configurations. For example, the mass flow rate ranges on the main MFCs and the aux MFCs may both be set around 55 SLM. The conventional system may need a large amount of carrier gas (e.g., hydrogen (H₂)) flowing into the each of the auxiliary injection ports to maintain a reasonable signal to noise ratio. Such conventional system may lack the resolution and control of the auxiliary injection ports when their mass flow rate range is comparable with the mass flow rate range of the main injection ports, and may be unable to decouple the tuning of the resistivity and the thickness cross the substrates. As such, the conventional system may not be able to meet customer requirements to achieve optimal resistivity and thickness profiles and minimal interference in the tuning process.

In contrast with the conventional system, in system 300, the main MFCs and aux MFCs may be set individually to control the mass flow rate range of each of the main MFCs and the aux MFCs. The main MFCs and aux MFCs may have mismatched configurations such that a second mass flow rate range of the aux MFCs may be substantially lower that the first mass flow rate range of the main MFCs. In some examples, a value in the second mass flow rate range may be between about 1% and about 10% of a value in the first mass flow rate range. For example, a value in the second mass flow rate range may be between about 1% and about 2% of a value in the first mass flow rate range, or between about 2% and about 4% of a value in the first mass flow rate range, or between about 4% and about 6% of a value in the first mass flow rate range, or between about 6% and about 8% of a value in the first mass flow rate range. Limiting the mass flow rates through the auxiliary header to within these ranges may decouple adjustments made to the auxiliary MFCs for resistivity from cross-substrate thickness uniformity. Decoupling resistivity adjustments from cross-substrate material layer thickness variation may in turn limit the need for both cross-substrate resistivity adjustments (e.g., for cross-substrate resistivity uniformity) and cross-substrate material layer thickness adjustments (e.g., cross-substrate material layer thickness uniformity).

In some examples of system 300, the first mass flow rate range does not overlap with the second mass flow rate range. In some examples, the first mass flow rate range of the main MFCs is about 30 to about 110 standard liter per minute (SLM), for example, between about 30 SLM and about 40 SLM, or between about 40 SLM and about 50 SLM, or between about 50 SLM and about 60 SLM, or between about 60 SLM and about 70 SLM, or between about 70 SLM and about 80 SLM, or between about 80 SLM and about 90 SLM, or between about 90 SLM and about 100 SLM, or between about 100 SLM and about 110 SLM. Flow rates within these ranges may enable the deposition of silicon-containing epitaxial material layers at deposition rates providing acceptable throughput, and thereby optimize the cost of ownership. The second mass flow rate range of the aux MFCs is about 1 to about 7 SLM, for example, between about 1 SLM and about 3 SLM, or between about 3 SLM and about 5 SLM, or between about 5 SLM and about 7 SLM. Flow rates within these ranges may enable doping silicon-containing epitaxial material layers deposited at deposition rates providing acceptable throughput with levels of dopant that provide sheet resistivity acceptable for semiconductor devices.

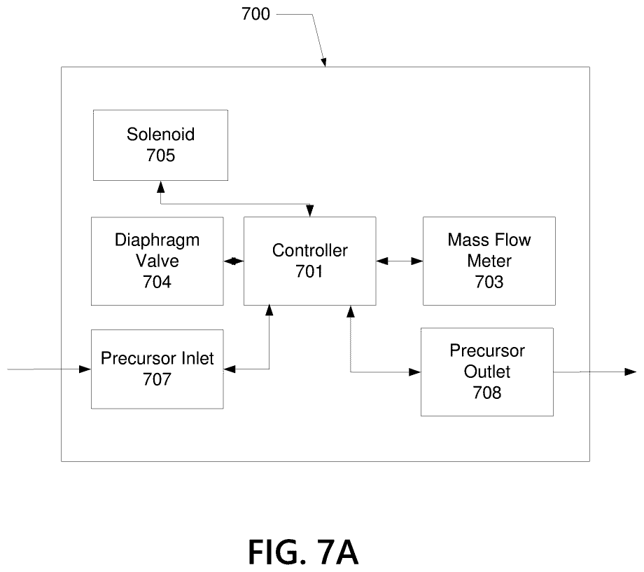

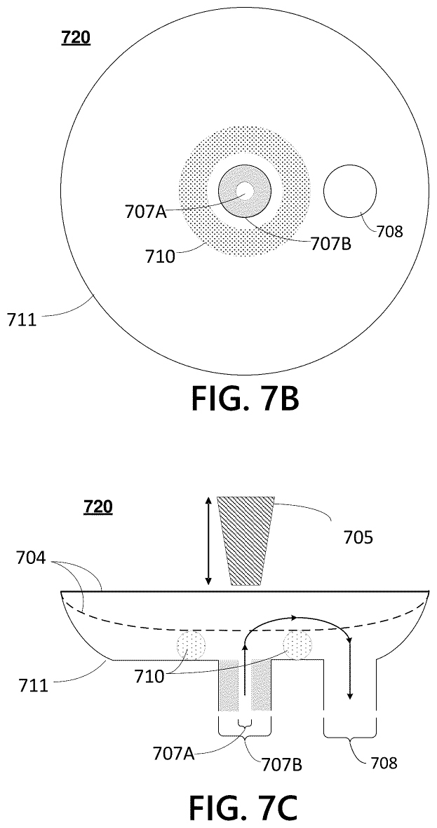

In some examples of system 300, the main MFCs and the aux MFCs may have different flow-rate limiting structures that determine, at least partially, the differences in their mass flow rate ranges. In some examples, each of the main MFCs and the aux MFCs may include a flow metering value that includes an inlet port, a control valve (e.g., diaphragm valve), and an outlet port. The control valve in a first position may fluidly couple the inlet port to the outlet port. The control valve in a second position may fluidly decouple the inlet port from the outlet port. The inlet port, the control valve, and the outlet port in each of the main MFCs may form a first mass flow-rate limiting structure that limits a mass flow rate of the gas to within the first mass flow rate range. The inlet port, the control valve, and the outlet port in each of the aux MFCs may form a second mass flow-rate limiting structure with a second effective flow area that limits the mass flow rate of the gas to within the second mass flow rate range. The first and the second mass flow-rate limiting structures may include different inlet port cross sections, different outlet port cross sections, different inlet port diameters, different diaphragm-to-valve seat spacing, different outlet port diameters, or different inlet port orifices, output port orifices, or different orifice plates with different effective flow areas. For example, the inlet ports in the flow metering valves included in the aux MFCs may have a smaller diameter or cross section, resulting a smaller effective flow area than that of the inlet ports in the flow metering valves included in the main MFCs, which have a larger diameter or cross section. The differences in the flow-rate limiting structures may provide different accuracies in metering the flow rates of the main MFCs and the auxiliary MFCs. The details of these flow-rate limiting structures will be further discussed in FIGS. 7A-7C.

For example, the main MFCs 340a of main header 310 may have an orifice plate 350a. The aux MFCs 340b of aux header 320 may have an orifice plate 350b. The orifice plate 350a may have an orifice opening greater than that on the orifice plate 350b. In another example, the main MFCs and the aux MFCs may have different restrictors. In still another example, the main MFCs and the aux MFCs may have different inlet and/or outlet port on a valve within the corresponding MFC. Due to these differences in flow-rate limiting structures, the plurality of main MFCs may have a first effective flow area, and the plurality of aux MFCs may have a second effective flow area, and where the second effective flow area may be less than the first effective flow area. In some examples of system 300, each of the main MFCs may comprise a first sensor configured to measure a first flow rate of gasses over a first mass flow rate range, and each of the aux MFCs may comprise a second sensor configured to measure a second flow rate of gasses over a second mass flow rate range, and the second sensor may have a higher sensitivity than the first sensor. For example, the sensors and gas valves in the aux MFCs may be adapted to monitor and meter the relatively low mass flow range of the gas flow via the auxiliary injection ports. In system 300, there may be relatively small amount of carrier gas (e.g., hydrogen (H₂)) flowing into each of three auxiliary injection ports compared with the relatively large amount of carrier gas (e.g., hydrogen (H₂)) flowing into each of the seven main injection ports. Such aux MFCs with higher sensitivity may provide the resolution and more precise control of the auxiliary injection ports with relatively lower mass flow rate range, which may afford the ability to tune the resistivity profile independently from the thickness profile cross substrate 330. For example, a controller (not shown in FIG. 3) may control the deposition of a material layer on a substrate (e.g., wafer 330) via control of the plurality of main MFCs and the plurality of aux MFCs. The controller may adjust, via control of the plurality of main MFCs, a cross-substrate thickness variation of the material layer. The controller may adjust, via control of the plurality of aux MFCs and independent of the cross-substrate thickness variation, cross-substrate resistivity variation of the material layer. The mass flow rate ratios among three aux MFCs may be further controlled and tuned to achieve a more uniform profile at the pyro center and pyro edge of the substrate 330. For example, the controller may adjust, via the plurality of aux MFCs, a distribution of a flow of the carrier through the plurality of auxiliary injection ports to the deposition chamber to tune the cross-substrate resistivity variation of the material layer. The controller may adjust, via the plurality of aux MFCs, a distribution of a flow of the dopant between the plurality of main injection ports coupled to the main header and the plurality of auxiliary injection ports coupled to the auxiliary header to tune the cross-substrate resistivity variation of the material layer.

In contrast with the conventional system which have uniform injector setting on the MFCs, system 300 may have mismatched main MFCs and aux MFCs. The main MFCs may enable flow tuning laterally (i.e. side-to-side flow tuning) such that any one of the main MFCs provides flow differing from another of the first plurality of MFCs, e.g., between about 5% and about 20% of the total flow from the main header. This total flow range may enable other factors that drive cross-substrate material layer thickness variation (such as heating non-uniformity) to be compensated for using lateral variation in precursor flow rate at the injection manifold. Likewise, the aux MFCs may enable flow tuning laterally (i.e. side-to-side flow tuning) such that any one of the aux MFCs may provide flow differing from another of the aux MFCs, e.g., between about 20% and about 50% of the total flow from the auxiliary header. This total flow range may enable other factors that drive cross-substrate material layer resistivity (such as lateral variation in precursor flow rate from the main header) to be compensated for using lateral variation in precursor flow rate at the injection manifold.

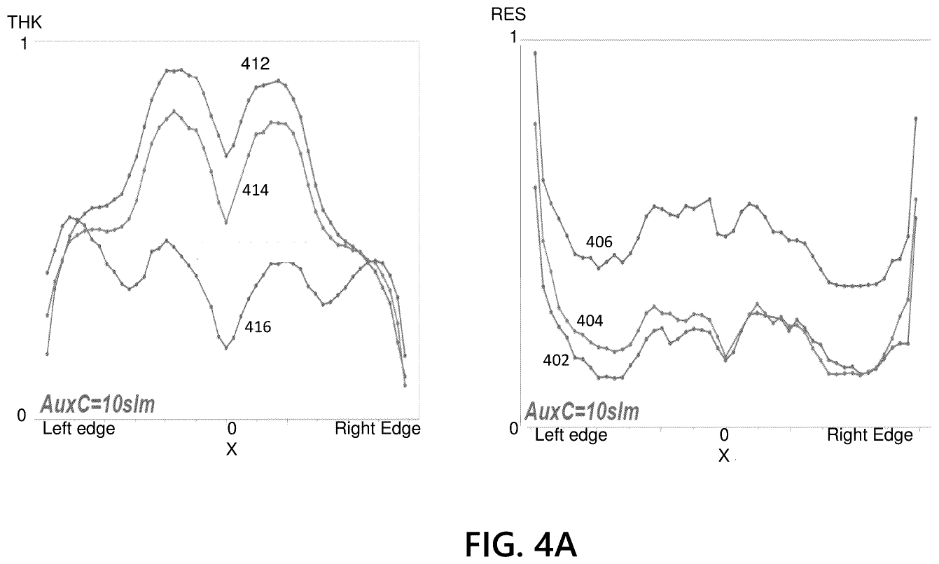

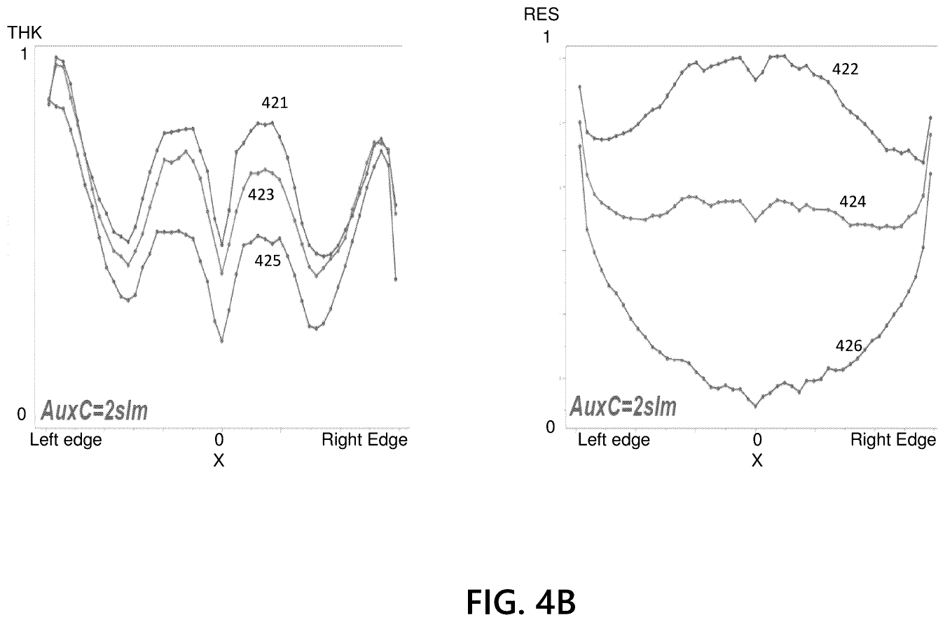

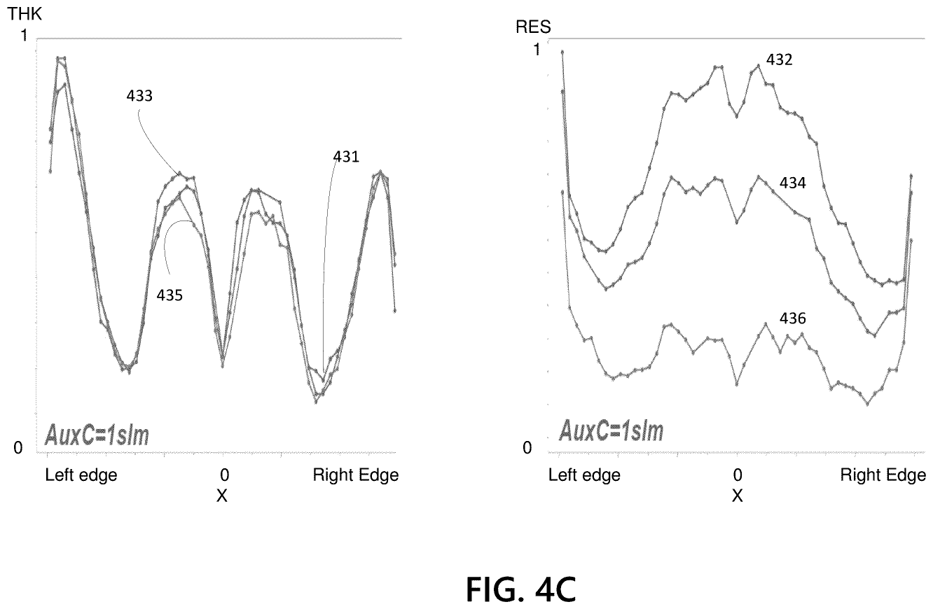

FIG. 4A-4C show example graphs illustrating tuning of the thickness profile and resistivity profile according to one or more aspects of the disclosure. The flow rate of the aux header may be reduced relative to the flow rate of the main header, so that there would be less dilution effect and interference on the tuning of the thickness profile. Several experiments have been carried out to explore the optimal range of the flow rate on the aux header relative to that of the main AGI.

In FIG. 4A, the carrier gas (e.g., hydrogen (H₂)) is introduced into the reaction chamber via three auxiliary injection ports at the flow rate of 10 SLM, while the flow rate of the main injection ports may be maintained at about 60 SLM. The graphs 412, 414 and 416 representing the thickness profiles that are displayed on the left-hand side of FIG. 4A, and the graphs 402, 404 and 406 representing the resistivity profiles that are displayed on the right-hand side of FIG. 4A. For example, the resistivity profile is tested under three scenarios: 1) graph 402 corresponding to the flow ratio of the carrier gas distributed as A1%, A2% and A3% among three aux MFCs; 2) graph 404 corresponding to the flow ratio of the carrier gas distributed as B1%, B2% and B3% among three aux MFCs; and 3) graph 406 corresponding to the flow ratio of the carrier gas distributed as C1%, C2% and C3% among three aux MFCs. A1, A2, A3, B1, B2, B3, C1, C2 and C3 may range from 0% to 100%. For example, A1, A2 and A3 may constitute 100% of the total flow of the carrier gas on the aux header. Likewise, the thickness profile is tested under similar scenarios: 1) graph 412 corresponding to the flow ratio of the carrier gas distributed as A1%, A2% and A3% among three aux MFCs; 2) graph 414 corresponding to the flow ratio of the carrier gas distributed as B1%, B2% and B3% among three aux MFCs; and 3) graph 416 corresponding to the flow ratio of the carrier gas distributed as C1%, C2% and C3% among three aux MFCs.

In the context of the flow rate of 10 SLM on the aux header as shown in FIG. 4A (where for example, the mass flow rate of the aux header is lower compared to the mass flow rate of the main header (e.g., 60 SLM)), changing the flow ratios of the carrier gas to tune the resistivity profile may cause a drastic change on the thickness profile. For example, switching from graph 402 to graph 406 on the resistivity profile result in corresponding changes from graph 412 to graph 416 on the thickness profile. This indicates that tuning the resistivity profile is strongly coupled with the thickness profile, when the carrier gas associated with the auxiliary injection port (i.e., aux header carrier gas) is at the mass flow rate of 10 SLM. At 10 SLM, FIG. 4A demonstrates a strong coupling effect between the thickness and resistivity, and a low resistivity tunability.

The mass flow rate of the aux header carrier gas may be further reduced to 2 SLM in FIG. 4B. In FIG. 4B, the carrier gas, such as hydrogen (H₂) is introduced into the reaction chamber via three aux injection ports at the mass flow rate of 2 SLM, while the mass flow rate of the main injection ports is maintained at about 60 SLM. Three graphs 421, 423 and 425 representing the thickness profiles are displayed on the left-hand side of FIG. 4B, and three graphs 422, 424 and 426 representing the resistivity profiles are displayed on the right-hand side of FIG. 4B. For example, the resistivity profile is tested under three scenarios: 1) graph 422 corresponding to the flow ratio of the carrier gas distributed as A1%, A2% and A3% among three aux MFCs; 2) graph 424 corresponding to the flow ratio of the carrier gas distributed as B1%, B2% and B3% among three aux MFCs; and 3) graph 426 corresponding to the flow ratio of the carrier gas distributed as C1%, C2% and C3% among three aux MFCs. Likewise, the thickness profile is tested under these similar scenarios. At the flow rate of 2 SLM on the aux header as shown in FIG. 4B (where for example, the mass flow rate of the aux header is much lower compared to the mass flow rate of the main header (e.g., 60 SLM)), changing the flow ratios of the carrier gas on the resistivity profile may still cause some change on the thickness profile. But three thickness graphs 421, 423 and 425 start to converge, causing significantly less impact on the thickness profile compared to FIG. 4A (where the mass flow rate of the carrier gas is at 10 SLM on the aux header). This indicates that tuning the resistivity profile has some reduced correlation with the thickness profile, when the aux header carrier gas is at the mass flow rate of 2 SLM. At 2 SLM, FIG. 4B demonstrates a significantly reduced coupling effect between the thickness and resistivity, and a sufficient resistivity tunability.

The flow rate of the aux header carrier gas may be further reduced to 1 SLM in FIG. 4C, showing a decoupling of thickness and resistivity. In FIG. 4C, the carrier gas H₂ is introduced into the reaction chamber via three aux injection ports at the mass flow rate of 1 SLM, while the mass flow rate of the main injection ports is maintained at about 60 SLM. Three graphs 431, 433 and 435 representing the thickness profiles are displayed on the left-hand side of FIG. 4C, and three graphs 432, 434 and 436 representing the resistivity profiles are displayed on the right-hand side of FIG. 4C. For example, the resistivity profile is tested under three scenarios: 1) graph 432 corresponding to the flow ratio of the carrier gas distributed as A1%, A2% and A3% among three aux MFCs; 2) graph 434 corresponding to the flow ratio of the carrier gas distributed as B1%, B2% and B3% among three aux MFCs; and 3) graph 436 corresponding to the flow ratio of the carrier gas distributed as C1%, C2% and C3% among three aux MFCs. Likewise, the thickness profile is tested under these similar scenarios. At the mass flow rate of 1 SLM on the aux header as shown in FIG. 4C (where for example, the mass flow rate of the aux header is extremely low compared to the mass flow rate of the main header (e.g., 60 SLM)), changing the flow ratios of the carrier gas on the resistivity profile may cause minimal change on the thickness profile, and three thickness graphs 431, 433 and 435 have substantially converged. This indicates that tuning the resistivity profile may be decoupled with the thickness profile, when the aux header carrier gas is at the mass flow rate of 1 SLM. At 1 SLM, FIG. 4C demonstrates a negligible coupling effect between the thickness and resistivity, and a more sufficient resistivity tunability.

One goal of tuning the resistivity profile may be to increase the uniformity of the resistivity profile, so that the high to low variation may be minimized. This goal might not be achieved in a conventional system, because changing the injector settings, both thickness and resistivity would change accordingly. By using a substantially smaller mass flow rate range on the aux header, the resistivity profile may be tuned with an adjustment of flow on three aux MFCs independently from the tuning of the thickness profile. The resistivity graphs may be tuned to be relatively flat to achieve a more uniformed resistivity profile, while the tuning process would cause no or minimal interference to the thickness profile.

The uniformity of the resistivity profile may be reflected in the flatness of the resistivity graphs in FIG. 4C. The x-axis illustrates the distance from the center of the substrate in a diameter scan. For example, the left end of the x-axis indicates the left edge of the substrate, 0 is center of the substrate, and the right end of the x-axis indicates the right edge of the substrate. Among three resistivity graphs in FIG. 4C, graph 434 provides a better uniformity as the resistivity remains relatively flat across the substrate. Graph 434 corresponds to the flow ratios of B1%, B2% and B3% distributed among three aux MFCs. The flow ratios may be tuned to achieve an improved uniformity of the resistivity profile without much impact on the thickness profile. In this manner, the system may be tuned to identify an optimal flow ratio on the aux MFCs that not only decouples the thickness and resistivity profiles, but also increases the substrate to substrate stability. Based on the testing scenarios illustrated in FIGS. 4A-4C, the gas injection system may be adapted to reduce the flow rate on the aux MFCs to implement the mechanism to decouple the tuning of the thickness and resistivity profiles.

As illustrated in FIGS. 4A to 4C, reducing the flow rate of the carrier gas on the aux header may cause less dilution and interference with the main AGI. If the main header is set at the flow rate of 60 SLM and the aux header carrier gas is set at the flow rate of 10 SLM, the flow ratio of the main header to the aux header is 6:1 and there still may be interference between the thickness and resistivity tuning. If the main header is kept at the same flow rate of 60 SLM and the aux header is set at 1 SLM, the flow ratio of the main header to the aux header is 60:1 and there is no or minimal interference between the thickness and resistivity tuning. Under this condition, the aux header may not have much dilution effect on the main header, and the thickness profile may be tuned first by changing the injector settings (e.g., the seven MFCs mass flow rates) on the main header to get the desired thickness profile. The resistivity profile may be tuned subsequently, by adjusting the injector settings (e.g., the three MFCs mass flow rates) on the aux header. Reducing the mass flow rate of the carrier gas on the aux header may minimize the interference effect on thickness, which have already been tuned to the desired thickness profile. As such, the thickness profile may be decoupled from the resistivity profile and the crosstalk between the thickness and resistivity tuning may be eliminated.

In the example of FIGS. 4A to 4C, there are three aux injection ports (e.g., Aux 1, Aux 2 and Aux 3) in the gas injection system, whose mass flow rates may be controlled by the corresponding aux MCFs. The conventional system may use the aux header settings similar as the main header settings. For example, in the conventional system, the aux header mass flow rate may be set at 55 SLM, which is the same or similar as the mass flow rate on the main header. The aux MCFs including the flow sensors and gas valves may have similar configurations to those on the main MCFs. In the example of 4A to 4C, a controller may be adapted to implement a substantially smaller mass flow rate on the aux header. The aux MCFs may be adapted to monitor and meter a substantially smaller mass flow rate range, such as about 1 SLM to about 7 SLM. Aux 1-3 may have flow-rate limiting structures that are adapted to measure a much lower mass flow rate range. Such system (e.g., system 300) may be used to tune the thickness profile of the material layer deposited onto the substrate by changing the settings on the main header to achieve a desired thickness profile.

This system may be used to further tune the resistivity profile of the material layer deposited onto the substrate. Although it is possible to have the same flow on each of Aux 1-3, it is also possible to have different mass flow rates and distributions on each of Aux 1-3. For example, the flow ratios may be set at Aux 1 A1%, Aux 2 A2%, and Aux 3 A3%. Given that the aux header is set at a mass flow rate substantially smaller than that of the main header, tuning the flow ratios on Aux 1-3 would change the resistivity profile, but may not cause much impact on the thickness profile.

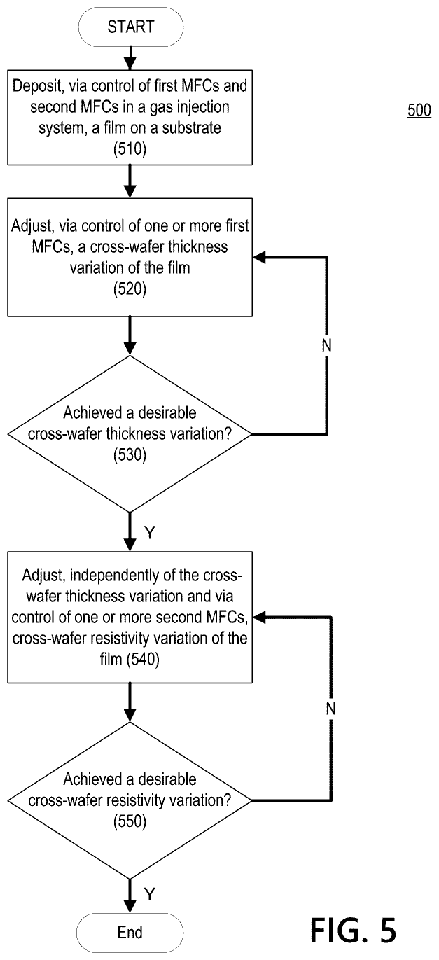

FIG. 5 shows an example flowchart describing a process for decoupling the tuning of thickness and resistivity in a gas injection system. At step 510, a gas injection system may deposit a material layer on a substrate, via control of a plurality of first mass flow controllers (MFCs) and a plurality of second MFCs. A controller in the gas injection system may configure the one more first MFCs (e.g., main MFCs) and the plurality of second MFCs (e.g., aux MFCs). The gas injection system may include a main header (e.g., a main manifold) comprising the plurality of first MFCs. The controller may configure the plurality of first MFCs to have a first mass flow rate range. The main header may be coupled to a precursor source, a dopant source and a carrier source.

The controller may configure the plurality of second MFCs. The gas injection system may include an aux header (e.g., an aux manifold) comprising the plurality of second MFCs. The controller may configure the plurality of second MFCs to have a second mass flow rate range. The second mass flow rate range may be different from the first mass flow rate range. In some examples, the first mass flow rate range may not overlap with the second mass flow rate range. The aux header may be coupled to the dopant source and the carrier source.

In operation, the carrier source may comprise one or more tanks containing a carrier selected from the group consisting of nitrogen, hydrogen, and helium. The precursor source may comprise one or more tanks containing a precursor selected from the group consisting of trichlorosilane, dichlorosilane, silane, disilane, trisilane, and silicon tetrachloride. The dopant source may comprise one or more tanks containing a dopant selected from the group consisting of germane, diborane, phosphine, arsine, and phosphorus trichloride. The controller may be communicatively coupled with the plurality of first MFCs and the plurality of second MFCs to control the operations of the MFCs.

The gas injection system may further include an injection flange with a plurality of main injection ports and a plurality of auxiliary injection ports. The plurality of first MFCs may be configured to control a first flow of the precursor, the dopant and the carrier through the plurality of main injection ports to a deposition chamber. The plurality of second MFCs may be configured to control a second flow of the dopant and the carrier through the plurality of auxiliary injection ports to the deposition chamber. Through the operation of the plurality of first MFCs and second MFCs, the gas injection system may control the deposition of the material layer on the substrate.

In some examples, the gas injection system may include seven first MCFs (e.g., main MFCs) and three second MCFs (e.g., aux MFCs). It is possible for the gas injection system to have different numbers of main MCFs and aux MCFs. The main MFCs and aux MFCs may have different flow-rate limiting structures and configurations adapted to monitor and meter different mass flow ranges. For example, the plurality of main MFCs may be configured to monitor and meter a first mass flow rate range and the plurality of aux MFCs may be configured to monitor and meter a second mass flow rate range. In some examples, a value in the second mass flow rate range may be between about 1% and about 10% of a value in the first mass flow rate range. The plurality of main MFCs may define a first effective flow area, and the plurality of aux MFCs may define a second effective flow area. The second effective flow area may be substantially smaller than the first effective flow area. The first effective flow area may govern flow through the main MFCs when they are fully open. The second effective flow area may govern flow through the second MFCs when they are fully open. The effective flow area may be defined by one or more of a conduit, an orifice plate, and/or a restrictor. The conduit may include an inlet port and/or outlet port on a valve within the corresponding MFC. For example, each of the main MFCs may have a larger orifice plate than that of the aux MFCs.

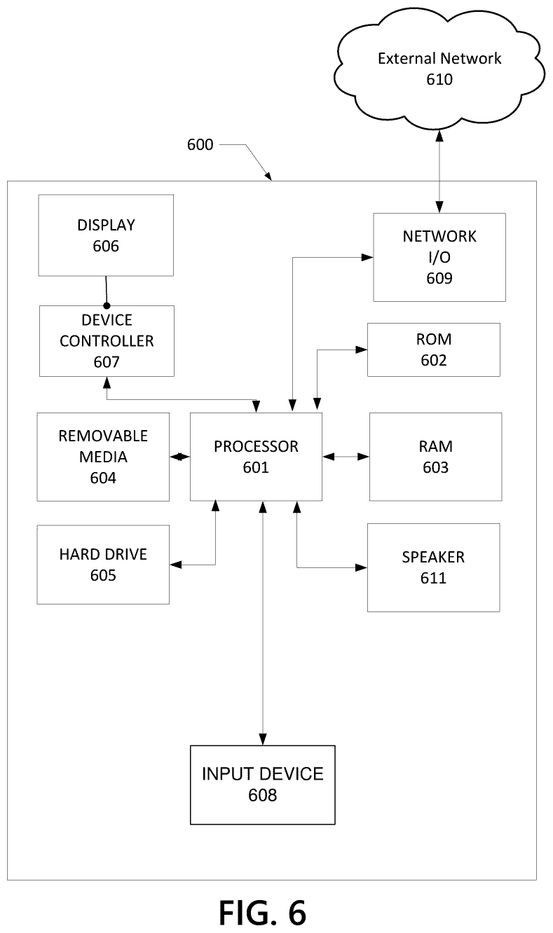

The MFCs may include pressure transient insensitive (PTI) mass flow controllers that may minimize process gas flow variation due to pressure and temperature fluctuations. The MFCs may include flow sensors used to monitor mass flow rates of gas mixtures and to provide real-time and/or historical mass flow rate information to a user. The flow sensors may be communicatively coupled to a controller, such as a computing device illustrated in FIG. 6. The controller may receive data from the flow sensors that monitor the mass flow rates and send instructions to gas valves to control and adjust the mass flow rates. The flow sensors may be connected to gas valves to provide controlled flow ratio of the gases through the gas valves. In some examples, the flow sensors may include thermal mass flow sensors or pressure drop based flow sensors.

At step 520, the controller may adjust, via control of a plurality of first MFCs, a cross-substrate thickness variation of the material layer. For example, the controller may determine, a first mass flow rate of carrier source associated with the plurality of first MFCs. The first MFCs may be coupled with a first plurality of flow sensors. The first flow sensors may monitor parameters such as a mass flow rate of the carrier source (e.g., hydrogen (H₂)) for each of the first MFCs. The first flow sensors may send the sensor data including the mass flow rate to the controller. The controller may receive the sensor data from the first flow sensors, and monitor the mass flow rates of the first MFCs.

The controller may control of a plurality of first MFCs to adjust a cross-substrate thickness variation of the material layer. In turn, the plurality of first MFCs may meter and control a first flow of the precursor, the dopant and the carrier through a plurality of main injection ports to the deposition chamber. The thickness variation of the material layer may be tuned by changing a mass flow rate of the first MFCs. The thickness variation of the material layer may be further tuned by changing a distribution of a flow of the gas through the plurality of main injection ports to the deposition chamber. For example, the thickness variation may be tuned by adjusting a distribution of a flow of carrier among seven main MFCs.

At step 530, the controller may determine whether a desirable cross-substrate thickness variation has been achieved. If the desirable cross-substrate thickness variation has been achieved, the process proceeds to step 540; otherwise, the process returns to step 520 to continue to adjust the cross-substrate thickness variation via control of the first MFCs.

At step 540, the controller may adjust, independently of the cross-substrate thickness variation and via control of the plurality of second MFCs, cross-substrate resistivity variation of the material layer. The second MFCs may be coupled with second flow sensors. The second flow sensors may monitor parameters such as a second mass flow rate of the dopant source or the carrier source (e.g., H₂) on each of the second MFCs. The flow sensors may send the sensor data including the mass flow rate to the controller. The controller may receive the sensor data from the second flow sensors and monitor the second mass flow rate on the second MFCs.

The controller may control of the plurality of second MFCs to adjust a cross-substrate resistivity variation of the material layer. In turn, the plurality of second MFCs may meter and control a second flow of the dopant and the carrier through a plurality of auxiliary injection ports to the deposition chamber. The second MFCs may be coupled with a plurality of gas valves which may be adjusted to change the effective flow area of the second MFCs. Accordingly, the second mass flow rate of the second MFCs may be adjusted, which may adjust the cross-substrate resistivity variation of the material layer.

The controller may control the second mass flow rate of the second MFCs to adjust a resistivity profile of a deposited material layer independently from a thickness profile of the deposited material layer. The controller may initially adjust the first mass flow rate to tune the thickness profile of the deposited material layer independently from the resistivity profile. For example, as discussed in steps 520-530, the controller may adjust the first mass flow rate of the first MFCs, and a desirable thickness profile may be achieved. The controller may adjust the second mass flow rate to tune the resistivity profile. For example, the controller may adjust the second plurality of gas valves to change the second mass flow rate, and the second plurality of gas valves may be coupled with the second MCFs. For example, if the first mass flow rate is about 30 to about 110 SLM, the second flow rate may be tuned to be about 1 to about 7 SLM, indicating that the second mass flow rate range may be substantially lower than the first mass flow rate range. An optimal ratio between the first and second mass flow rates may be selected to minimize the cross-talk between the thickness and the resistivity, while maintaining a stability of the flow of the dopant or the carrier via the aux header.

After tuning the second mass flow rate to be substantially lower than the first mass flow rate, changing the second mass flow rate may cause minimal impact to the thickness profile. The controller may adjust the second mass flow rate to achieve a desirable resistivity profile independently from the thickness profile. For example, the first mass flow rate may be tuned to be about 55 SLM to reach an optimal thickness profile and the second mass flow rate may be tuned to be about 1 SLM to achieve an optimal resistivity profile.

Tuning the resistivity profile may include adjusting a distribution of the carrier source through the plurality of auxiliary injection ports to the deposition chamber. Each of the second MFCs on the aux header may contribute a portion of the aux header total flow (e.g., 3 SLM), and adjustment of any one of the second MFCs may alter the portion of aux header total flow through each of the second MFCs. After the aux header flow rate is set at an optimal range or value (e.g., 3 SLM), the resistivity profile may be tuned by adjusting the distribution of the total flow on three aux MFCs. For example, under condition 1, the flow ratios among three aux header MFCs may be initially distributed as 33%, 33%, 33%. Under condition 2, the flow ratios among three aux header MFCs may be subsequently distributed as 25%, 50%, 25%. The controller may compare the resistivity profiles under these conditions, and determine, for example, that condition 2 generates a better uniformity on the resistivity profile.

Tuning the resistivity profile may include adjusting a distribution of the dopant source carried by a plurality of main injection port on the main header and the plurality of auxiliary injection port on the aux header. In one example, the amount of P-dopant (carried on the main header) and A-dopant (carried on the aux header) may be at approximately equal amount. In another example, A-dopant may be set at 80%, P-dopant may be set at 20%, and ratio of the dopant source carried by the second header (e.g., the aux header) and that carried by the first header (e.g., the main header) is 1 to 4.

At step 550, the controller may determine whether a desirable cross-substrate resistivity variation has been achieved. If the desirable cross-substrate resistivity has not been achieved, the process returns to step 540 to continue to adjust the cross-substrate resistivity variation via control or the second MFCs. Otherwise, the process terminates. Although steps 520-550 have been sequentially illustrated in FIG. 5, it is possible for these steps to be performed in parallel or in any order. For example, steps 520 and 540 may be performed in parallel such that the cross-substrate thickness variation and cross-substrate resistivity variation may be adjusted at the same time. It is also possible to perform step 540 before step 520. It is further possible for steps 530 and 550 to be performed in parallel or in any order (e.g., step 530 to be performed before step 550, or step 550 to be performed before step 530).

FIG. 6 depicts an example of a computing device that may be used in implementing one or more aspects of the disclosure. The computing device may be a device for controlling the systems (e.g., 100, 200, 300) and performing the processes (e.g., 500) described herein. For example, one or more devices and components as described herein (e.g., the controller) may be implemented with the device shown in FIG. 6.

The term “network” as used herein and depicted in the drawings refers not only to systems in which remote storage devices are coupled together via one or more communication paths, but also to stand-alone devices that may be coupled, from time to time, to such systems that have storage capability. An example system architecture 600 may be used according to one or more illustrative aspects described herein. The system 600 may have a processor 601 for controlling overall operation of the system and its associated components, including read-only memory (ROM) 602, random access memory (RAM) 603, removable media 604, a hard drive 605, a display device 606, a device controller 607, an input device 608, a network input/output (I/O) device 609, and a speaker 611.

The input device 608 may include a mouse, keypad, touch screen, scanner, optical reader, and/or stylus (or other input device(s)) through which a user of the system 600 may provide input. One or more speakers 611 may provide audio output, and the display device 606 may provide textual, audiovisual, and/or graphical output. Software may be stored within the removable media 604 and/or the hard drive 605 to provide instructions to processor 601 for configuring the system 600 into a special purpose computing device in order to perform various functions as described herein. For example, the removable media 604 and/or the hard drive 605 may store software used by the system 600, such as an operating system, application programs, and/or an associated database.

The system 600 may operate in a networked environment supporting connections to one or more remote computers or components, such as the flow sensors 230-248, gas valves 250-268, etc. The external network 610 may include a local area network (LAN) and a wide area network (WAN), but may also include other networks. When used in a LAN networking environment, the system 600 may be connected to the LAN through the network I/O 609 (e.g., a network interface or adapter). When used in a WAN networking environment, the system 600 may include a modem or other wide area network interface for establishing communications over the WAN, such as the Internet. It will be appreciated that the network connections shown are illustrative and other means of establishing a communications link between the computers may be used. The system 600 may be a mobile terminal (e.g., a mobile phone, a smartphone, a personal digital assistant (PDA), a laptop computer, etc.) including various other components, such as a battery, speaker, and antennas (not shown).

FIG. 7A illustrates an example mass flow metering valve of a mass flow controller (MFC), according to one or more aspects of the disclosure. As illustrated in FIG. 7A, system 700 include a controller 701, a mass flow meter 703, a diaphragm (or other type of control) valve 704, a solenoid 705, a precursor inlet port 707 and a precursor outlet port 708. In some examples, the main MFCs and the auxiliary MFCs may include a flow-rate limiting structure such as the flow metering valve. Specifically, the flow metering valve may include the diaphragm valve 704 coupled to a solenoid 705 and supported above a valve seat (e.g., valve seat 710 illustrated in FIG. 7B), an inlet port 707, and an outlet port 708. The inlet port 704, the diaphragm (or other type of) valve 704, and the outlet port 708 in a main MFCs may form a first mass flow-rate limiting structure that limits a mass flow rate of the gas to within a first mass flow rate range. The inlet port 704, the diaphragm (or other type of) valve 704, and the outlet port 708 in an auxiliary MFCs may form a second mass flow-rate limiting structure that limits the mass flow rate of the gas to within the second mass flow rate range.

FIGS. 7B and 7C illustrate a top and side view of an example diaphragm seat of the MFC, including example effective flow areas of a main MFC and an auxiliary MFC, according to one or more aspects of the disclosure. In the example, a valve 720 may include a bowl 711, having an inlet port 707, and an outlet port 708, through which a gas mixture may enter and exit the valve respectively. The main MFC and auxiliary MFC may have different effective flow areas through the value. In one example, the auxiliary MFCs may have an inlet port with a smaller diameter (labeled 707A and represented with a dashed line) resulting in a smaller effective flow area than that of the main MFCs, which have a larger diameter (labeled 707B). The valve may further include a valve seat 710 extending around the inlet port and separating the outlet port from the inlet port.

System 720 may include a solenoid 705 and a diaphragm 704 (not illustrated in FIG. 7B). The solenoid 705 may act as a transducer device that converts energy into linear motion to move the diaphragm 704. For example, the solenoid 705 may be coupled to a controller, which controls the movement of the diaphragm 704. The diaphragm 704 may be movable between a first position (illustrated as a solid line) and a second position (illustrated as a dashed line). In the first position, the diaphragm 704 is spaced apart from the valve seat 710 such that the inlet port 707 is fluidly coupled to the outlet port 708 (represented by the arrowed lines extending from the inlet port 707 to the outlet port 708). In the first position, a flow of the gas from the inlet port 707 through the valve seat 710 to the outlet port 708 is enabled. In a second position, the diaphragm 704 abuts the valve seat 710 and separates (e.g., fluidly decouples) the inlet port 707 from the outlet port 708, such that the flow of the gas from the inlet port 707 through the valve seat 710 to the outlet port 708 is inhibited.

The auxiliary MFCs and the main MFCs may be different in other flow-rate limiting structures including different inlet port cross sections or orifices, different outlet port cross sections or orifices, different inlet port diameters, different diaphragm-to-valve seat spacing, different outlet port diameters, or different orifice plates with different effective flow areas. These differences in flow-rate limiting structures may correspond to different accuracies in metering the flow rates on the main MFCs and the auxiliary MFCs. For example, the auxiliary MFCs may have a higher accuracy in metering the flow rate than the main MFCs. Due to the proximity of the inlet port 707 to the diaphragm 704, the hysteresis or lagging effect during flow may be limited relative to the conventional systems, given that the flow-rate limiting device (e.g., the solenoid 705) may be fluidly spaced from the diaphragm 704.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A gas injection system, comprising:
a main header comprising a plurality of first mass flow controllers (MFCs) having a first mass flow rate range, wherein the main header is coupled to a precursor source, a dopant source and a carrier source;
an auxiliary header comprising a plurality of second MFCs having a second mass flow rate range, wherein the second mass flow rate range is different from the first mass flow rate range, and wherein the auxiliary header is coupled to the dopant source and the carrier source; and
a controller comprising one or more processors and memory storing computer-readable instructions that when executed by the one or more processors, cause the controller to:
deposit, via control of the plurality of first MFCs and the plurality of second MFCs, a material layer on a substrate;
adjust, via control of the plurality of first MFCs, a cross-substrate thickness variation of the material layer; and
adjust, via control of the plurality of second MFCs and independent of the cross-substrate thickness variation, cross-substrate resistivity variation of the material layer.

2. The gas injection system of claim 1, wherein a value in the second mass flow rate range is between about 1% and about 10% of a value in the first mass flow rate range.

3. The gas injection system of claim 1, wherein the first mass flow rate range does not overlap with the second mass flow rate range.

4. The gas injection system of claim 1,
wherein each of the plurality of first MFCs and each of the plurality of second MFCs comprises an inlet port, a control valve, and an outlet port;
wherein the control valve in first position fluidly couples the inlet port to the outlet port; and
wherein the control valve in a second position fluidly decouples the inlet port from the outlet port.

5. The gas injection system of claim 4, wherein the control valve comprises a valve seat and solenoid-actuated movable diaphragm, wherein in the first position the diaphragm is spaced apart from the valve seat such that a flow of gas from the inlet port through the valve seat to the outlet port is enabled, and in the second position the diaphragm abuts the valve seat such that the flow of gas from the inlet port through the valve seat to the outlet port is inhibited.

6. The gas injection system of claim 4, wherein the inlet port comprises an orifice having an effective flow area that limits a mass flow rate of a gas from the inlet port through the control valve to the outlet port when the control valve is in the first position.

7. The gas injection system of claim 6, wherein the effective flow area of the orifice in each of the plurality of first MFCs is greater than the effective flow area of the orifice in each of the plurality of second MFCs.

8. The gas injection system of claim 6, wherein the effective flow area in each of the plurality of first MFCs limits the mass flow rate to within the first mass flow rate range, and the effective flow area in each of the plurality of second MFCs limits the mass flow rate to within the second mass flow rate range.

9. The gas injection system of claim 4, wherein:
the inlet port, the control valve, and the outlet port in each of the plurality of first MFCs form a first mass flow-rate limiting structure that limits a mass flow rate of a first gas to within the first mass flow rate range; and
the inlet port, the control valve, and the outlet port in each of the plurality of second MFCs form a second mass flow-rate limiting structure that limits the mass flow rate of a second gas to within the second mass flow rate range.

10. The gas injection system of claim 9, wherein the first and the second mass flow-rate limiting structures comprise different inlet port cross sections, different outlet port cross sections, different inlet port diameters, different diaphragm-to-valve seat spacing, different outlet port diameters, or different orifice plates with different effective flow areas.

11. The gas injection system of claim 1, wherein each of the plurality of first MFCs comprises a first sensor configured to measure a first flow rate of gasses over the first mass flow rate range, and each of the plurality of second MFCs comprises a second sensor configured to measure a second flow rate of gasses over the second mass flow rate range, and wherein the second sensor has a higher sensitivity than the first sensor.

12. The gas injection system of claim 1, wherein the first mass flow rate range is about 30 to about 110 standard liter per minute (SLM) and the second mass flow rate range is about 1 to about 7 SLM.

13. The gas injection system of claim 1, wherein the plurality of first MFCs comprise seven MFCs, and the plurality of second MFCs comprise three MFCs.

14. The gas injection system of claim 1, further comprising:
an injection flange comprising: a plurality of main injection ports corresponding one-to-one with the plurality of the plurality of first MFCs, and a plurality of auxiliary injection ports corresponding one-to-one with the plurality of second MFCs,
wherein the plurality of first MFCs are configured to control a first flow of a precursor, a dopant and a carrier through the plurality of main injection ports to a deposition chamber,
wherein the plurality of second MFCs are configured to control a second flow of the dopant and the carrier through the plurality of auxiliary injection ports to the deposition chamber.

15. The gas injection system of claim 14, wherein the computer-readable instructions, when executed by the one or more processors, further cause the controller to:
adjust, via the plurality of second MFCs, a distribution of a flow of the carrier through the plurality of auxiliary injection ports to the deposition chamber to adjust the cross-substrate resistivity variation of the material layer.

16. The gas injection system of claim 14, wherein the computer-readable instructions, when executed by the one or more processors, further cause the controller to:
adjust, via the plurality of second MFCs, a distribution of a flow of the dopant between the plurality of main injection ports on the main header and the plurality of auxiliary injection ports on the auxiliary header to adjust the cross-substrate resistivity variation of the material layer.

17. The gas injection system of claim 16, wherein a ratio of the dopant carried by the auxiliary header and the main header is 1 to 4.

18. The gas injection system of claim 1, wherein the computer-readable instructions, when executed by the one or more processors, further cause the controller to:
adjust, via the plurality of second MFCs, a cross-substrate dopant concentration variation to adjust the cross-substrate resistivity variation of the material layer.

19. The gas injection system of claim 1, wherein the carrier source comprises one or more tanks containing a carrier selected from the group consisting of nitrogen, hydrogen, and helium.

20. The gas injection system of claim 1, wherein the precursor source comprises one or more tanks containing a precursor selected from the group consisting of trichlorosilane, dichlorosilane, silane, disilane, trisilane, and silicon tetrachloride.

21. The gas injection system of claim 1, wherein the dopant source comprises one or more tanks containing a dopant selected from the group consisting of germane, diborane, phosphine, arsine, and phosphorus trichloride.

22. A gas flow control method comprising:
depositing, via control of a plurality of first MFCs and a plurality of second MFCs in a gas injection system, a material layer on a substrate, the plurality of first MFCs having a first mass flow rate range, and the plurality of second MFCs having a second mass flow rate range, wherein the first mass flow rate range is different from the second mass flow rate range, and wherein the plurality of first MFCs are connected by a main header to a precursor source, a dopant source and a carrier source, and the plurality of second MFCs are connected by an auxiliary header to the dopant source and the carrier source;
adjusting, via control of the plurality of first MFCs, a cross-substrate thickness variation of the material layer; and
adjusting, via control of the plurality of second MFCs and independent of the cross-substrate thickness variation, cross-substrate resistivity variation of the material layer.

23. The gas flow control method of claim 22, wherein a value in the second mass flow rate range is between about 1% and about 10% of a value in the first mass flow rate range.

24. The gas flow control method of claim 22, wherein the first mass flow rate range does not overlap with the second mass flow rate range.

25. A non-transitory, machine-readable medium storing instructions, wherein the instructions, when executed by one or more processors, cause the one or more processors to perform steps comprising:
depositing, via control of a plurality of first MFCs and a plurality of second MFCs in a gas injection system, a material layer on a substrate, the plurality of first MFCs having a first mass flow rate range, and the plurality of second MFCs having a second mass flow rate range, wherein the first mass flow rate range is different from the second mass flow rate range, and wherein the plurality of first MFCs are connected by a main header to a precursor source, a dopant source and a carrier source, and the plurality of second MFCs are connected by an auxiliary header to the dopant source and the carrier source;
adjusting, via control of the plurality of first MFCs, a cross-substrate thickness variation of the material layer; and
adjusting, via control of the plurality of second MFCs and independent of the cross-substrate thickness variation, cross-substrate resistivity variation of the material layer.
